(19) United States
(12) Patent Application Publication
(10) Pub. No.: US 2012/0236620 A1
(43) Pub. Date: Sep. 20, 2012

(54) Nonvolatile Memory Device and Manufacturing Method Thereof

(76) Inventor: Jai-Hoon Sim, Gyeonggi-do (KR)

(21) Appl. No.: 13/420,505

(22) Filed: Mar. 14, 2012

(30) Foreign Application Priority Data
Mar. 15, 2011 (KR) 10-2011-0022695

(51) Int. Cl. G11C 5/06; H01L 21/762

(52) U.S. Cl. 365/72; 438/424; 257/E21.546

(57) ABSTRACT

The present invention relates to a nonvolatile memory device and a manufacturing method thereof, the device comprising a plurality of word lines; a plurality of bit lines perpendicular to the word lines; and a plurality of memory cells including a transistor with a source connected to a source line, a gate, and a drain connected to a memory element, with the other end of the memory element connected to the bit lines. Between memory cells adjacent along a bit line, a gate terminal in a groove between the memory cells connects the gates in the memory cells to a word line. Memory cells adjacent along a word line are connected to one bit line contact point, and memory cells sharing a gate terminal are connected to different bit lines. Bit lines are disposed at the upper portion and source lines at the lower end of the memory cell.

### CLAIM TO FOREIGN PRIORITY

The present application claims priority to the filing date of Korean Patent Application No. 10-2011-0022695, filed Mar. 15, 2011.

### FIELD OF THE INVENTION

The present invention relates to a nonvolatile memory device having a cell size of 4 F² and a manufacturing method thereof.

### BACKGROUND OF THE INVENTION

Random Access Memory (RAM) is a computer memory device that is freely readable and recordable and generally used for temporarily storing data. Dynamic Random Access Memory (DRAM) is a kind of RAM wherein stored information is deleted as time passes, making it necessary to periodically reproduce the information. The structure is simple and integration is easy, such that DRAM is used as a large-capacity temporary memory device.

DRAM is the memory that creates the largest market in memories at the present time. DRAM is a memory device in which one MOS transistor and one capacitor make a pair and function as one bit. Data is recorded by storing charge in a capacitor in DRAM. Therefore DRAM is a volatile memory that needs to perform periodic refreshing in order to not lose data.

DRAM is composed of a plurality of word lines, a plurality of bit lines, and a plurality of memory cells electrically connected to the word lines and bit lines and composed of a transistor and a capacitor. The capacity of DRAM is determined by the number of memory cells in the DRAM chip.

Common DRAM has a memory cell size of 8 F² (8 F square) at the present time. In the DRAM, the widths of the word lines and bit lines, and the gap between the word lines and bit lines are the minimum processing dimension (F) and the area occupied by one memory cell is 8 F² (4 F×2 F). In order to manufacture large-capacity DRAM, it is necessary to reduce the minimum processing dimension (F) or to design and arrange memory cells densely with respect to a predetermined minimum processing dimension (F). As it becomes closer to the physical limits for reducing the minimum processing dimension (F), there has been a great tendency to reduce the memory cell size.

DRAMs having memory cell sizes of 6 F² (3 F×2 F) and 4 F² (2 F×2 F) have been developed to more densely arrange memory cells. DRAM having a memory cell size of 4 F² include a plurality of memory cells that is the most densely arranged, such that it is possible to provide a large-capacity DRAM.

NAND/NOR flash memory is a nonvolatile memory that does not lose the stored signals even if power is cut, such as in a hard disk and in contrast to DRAM. In particular, NAND flash memory has the highest degree of integration in common memories. Flash memory can be made small in comparison to a hard disk, is light and strong against a physical impact, the access speed is high, and the power consumption is small. Therefore flash memory is generally used as a storage medium for mobile products. However, flash memory has a defect that the speed is lower and the operation voltage is higher than those of DRAM.

Memories are used for various purposes. DRAM and flash memory have different characteristics and therefore are selected and used for different products. Recently, active attempts to develop and commercialize a memory having only the advantages of the two memories have been made. For example, Spin Transfer Torque RAM (STT-RAM), Phase Change RAM (PCRAM), Magnetic RAM (MRAM), Polymer RAM (PoRAM), and Resistive RAM (ReRAM) are typical.

In particular, STT-RAM in the memories is a memory that can operate with the highest speed of next-generation nonvolatile memories. It is not only a nonvolatile memory that keeps information even if power is not provided, but also a memory that can operate at high speed at the SRAM level. Therefore, STT-RAM has been actively developed.

Although STT-RAM has a structure similar to DRAM, the principle of storing and reproducing information is different. DRAM stores data as signals of 0 and 1 by keeping charge in a capacitor. SIT-RAM stores data as 0 and 1 in accordance with whether a memory storage device or a memory element, for example, a magnetic structure such as an Magnetic Tunneling Junction (MTJ), has magnetism. SIT-RAM is closer to MRAM in the next-generation memories in terms of the principle, in some meanings.

STT-RAM is a memory that has allowed commercialization of some products with a large capacity, using a resistance change according to a polarity change of a magnetic substance as a digital signal. SIT-RAM is not damaged by the radioactivity in space because it uses magnetism, therefore it may be the memory that has the greatest potential at the highest level of safety.

### SUMMARY OF THE INVENTION

An objective of the present invention is to apply a memory having a memory cell size of 4 F² to a nonvolatile memory device, on the basis of a metal wire arrangement technology of word lines and bit lines which is the same as that of the memories having a memory cell size of 8 F² or 6 F² of the related art.

A nonvolatile memory device according to the present invention comprises: a plurality of word lines disposed in parallel with each other in one direction; a plurality of bit lines disposed perpendicular to the word lines, in parallel with each other; and a plurality of memory cells in which a transistor is provided. A source line is electrically connected to a source terminal of the transistor, a gate line of the transistor is electrically connected to the word lines, a drain terminal of the transistor is connected to one end of a memory element, and the other end of the memory element is electrically connected to the bit line through a bit line contact point. The gate terminal of the transistor fills an associated one of grooves between two memory cells adjacent to each other in the direction of the bit line, and the memory cells simultaneously cover the sides of the two memory cells through the gate and an insulating layer formed between the two memory cells, in which the gate connected to one word line for a plurality of word lines is connected with the gates of the transistors of two memory cells adjacent to each other in the direction of the bit line, such that two memory cells adjacent to each other in the direction of the bit line share the gate connected to one word line. The gate terminal connected to the word line is disposed alternately with the gate connected to an adjacent word line. The bit line contact point connected to the bit line is disposed alternately with the bit line connected to an adjacent bit line. The gate terminals of the transistors of adjacent two memory cells are electrically connected to one gate terminal, the memory elements of two memory cells adjacent in the direction of a word line are electrically connected to one bit line contact point, the drain terminals of the transistors of two memory cells electrically connected to the gate terminal through the memory elements are electrically connected to different bit lines through different bit line contact points, and the bit line is disposed at the upper portion of the memory cell. The source line is disposed at the lower end of the memory cell, and two cells are connected to one gate trench.

A nonvolatile memory device according to the present invention includes: a plurality of word lines disposed in parallel with each other in one direction; a plurality of bit lines disposed perpendicular to the word lines in parallel with each other; and a plurality of memory cells in which a transistor is provided. A source line is electrically connected to a source terminal of the transistor, a gate line of the transistor is electrically connected to the word lines, a drain terminal of the transistor is connected to one end of a memory element, and the other end of the memory element is electrically connected to the bit line through a bit line contact point. The gate terminal of the transistor fills an associated one of grooves between two memory cells adjacent to each other in the direction of the bit line, and the memory cells simultaneously cover the sides of the two memory cells through the gate and an insulating layer formed between the two memory cells. The gate connected to one word line for a plurality of word lines is connected with the gates of the transistors of two memory cells adjacent to each other in the direction of the bit line such that two memory cells adjacent to each other in the direction of the bit line share the gate connected to one word line. The gate terminal connected to the word line is disposed alternately with the gate connected to an adjacent word line and the bit line contact point connected to the bit line is disposed alternately with the bit line connected to an adjacent bit line. The gate terminals of the transistors of adjacent two memory cells are electrically connected to one gate terminal, the memory elements of two memory cells adjacent in the direction of a word line are electrically connected to one bit line contact point, and the drain terminals of the transistors of two memory cells electrically connected to the gate terminal through the memory elements are electrically connected to different bit lines through different bit line contact points. The bit line is disposed at the upper portion of the memory cell, the source line is disposed at the lower end of the memory cell, and two cells are connected to one gate trench. The memory device further comprises a contact portion embedded in a semiconductor substrate and providing electric connection with the semiconductor substrate or a well formed in the semiconductor substrate, and the source terminal is in trench body contact with the semiconductor substrate.

The word lines and the bit lines may have a width and a gap of 2 F.

The memory cell may be formed with a size of 4 F².

The memory cell having a size of 4 F² may be applied to STT-RAM, R-RAM, or PCRAM.

A method of manufacturing a nonvolatile memory device on a semiconductor substrate according to the present invention includes: a step of forming a device separation layer that forms a first insulating layer on a semiconductor substrate by oxidizing, forms a second insulating layer on the first insulating layer, forms a plurality of grooves by etching the semiconductor substrate by using a Shallow Trench Isolation (STI) etching mask, and then forms an STI oxide region in the grooves; a step of forming an embedded body contact that oxide-etches a body contact region, forms an insulating spacer for opening the body contact region, and performs Chemical Mechanical Polishing (CMP) after filling the insulating spacer with P+ or P-poly and forming oxide in the remaining portion of the body contact region; a step of first forming source line etching that forms a groove at a predetermined depth in the semiconductor substrate through the first insulating layer and second insulating layer by using a first source line etching and forms a source line spacer on the sides of the groove formed by the first source line etching; a step of second forming source line etching that performs a second source line etching at a predetermined depth in the semiconductor substrate under the source line spacer formed on the sides of the groove by the first source line etching, and forms a source line junction N+ implanted region under and at the sides of a groove formed by the second source line etching; a step of forming a source line that fills the grooves formed by the first and second source line etchings with metal that forms a source line; a step of filling a source line that forms an oxide region in the remaining portion of the groove on the source line formed at a predetermined height in the groove; a step of removing an insulating layer and forming an N+ implanted region that removes the second insulating layer formed on the semiconductor substrate by performing CMP and forms an N+-implanted N+ implant region under and at the sides of the first insulating layer; a step of forming a gate that etches a region where a gate is formed in the STI oxide region, forms a gate oxide region on the sides and the bottom of the etched region, and forms a gate by filling the gate oxide region with gate metal; and a step of forming a word line that forms a word line at a predetermined height on the region where the gate is formed and forms a third insulating layer on the top and the sides of the word line.

The method may further include a step that forms a fourth insulating layer on the third insulating layer formed on the top and the sides of the word line, forms a storage node contact between the third insulating layer and the fourth insulating layer, forms a lower electrode and an upper electrode on the storage node contact, forms a memory element between the lower electrode and the upper electrode, and forms a bit line on the upper electrode.

According to the present invention, the memory cells of the nonvolatile memory are formed in the regions without the word lines and bit lines, under the word lines and bit lines. Therefore, a memory cell may be formed from a semiconductor substrate, and word lines and bit lines may be made of metal thereon. Further, it is not necessary to make a detailed structure in the word lines and the bit lines, and as a result the resistance and capacitance of the word lines and bit lines are not increased. Therefore it is possible to achieve a high-integrated memory cell with the advantages described above.

### BRIEF DESCRIPTION OF THE DRAWINGS

FIG. 1 is a circuit diagram showing STT-RAM having a memory cell size of 4 F² according to the present invention;

FIG. 2 is a three-dimensional diagram showing STT-RAM having a memory cell size of 4 F² according to an embodiment of the present invention;

FIGS. 3 to 12 are plan views and cross-sectional views showing the detailed processes in a method of manufacturing STT-RAM having a memory cell size of 4 F² according to an embodiment of the present invention; and

FIGS. 13 and 14 are diagrams showing a modification of a gate of a semiconductor substrate of the present invention.

### DETAILED DESCRIPTION OF THE DRAWINGS

Hereinafter, a nonvolatile memory device according to the present invention will be described in detail with reference to the accompanying drawings.

Further, STT-RAM (Spin Transfer Torque RAM) is exemplified as a nonvolatile memory where the present invention is applied, for the convenience of description. However, the present invention is not limited thereto and may be applied to other memory devices, such as Resistive RAM (R-RAM)) or Phase-Change RAM (PCRAM).

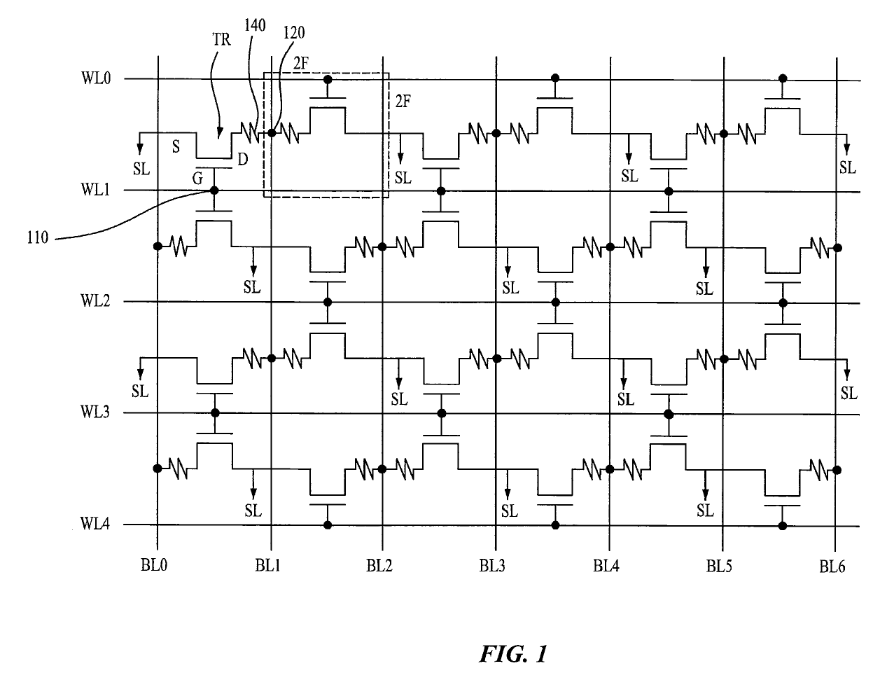

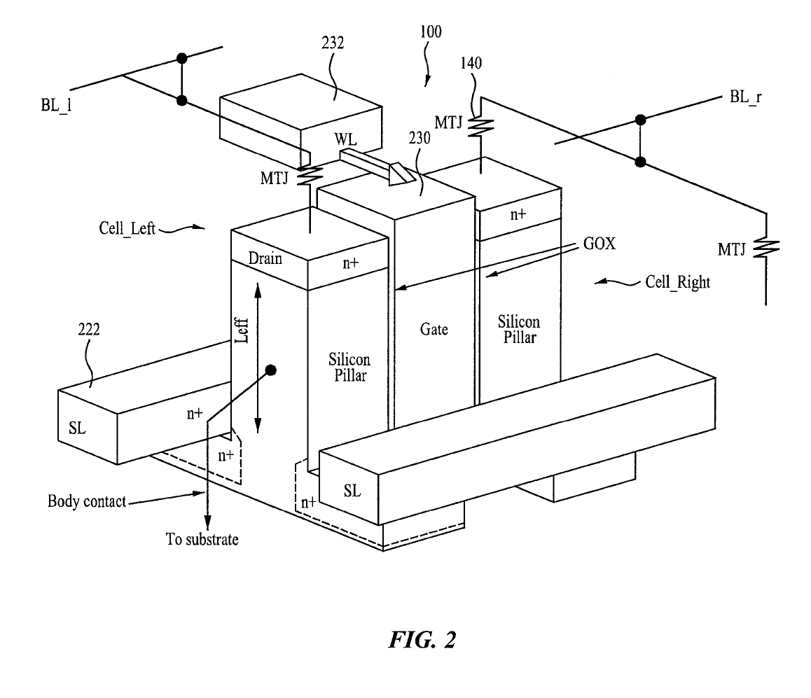

FIG. 1 is a diagram showing a memory cell arrangement in SST-RAM according to an embodiment of the present invention. In FIG. 1, a plurality of word lines WL0 to WL4 transversely extend with a width and a gap, preferably, of two times the minimum processing dimension (2 F), a plurality of bit lines BL0 to BL6 longitudinally extend with a width and a gap, preferably, of two times the minimum processing dimension (2 F), and memory cells 100 are disposed in the regions without word lines WL0 to WL4 and bit lines BL0 to BL6. The width and length of memory cells 100 are two times the minimum processing dimension (2 F). The number of memory cells 100 is the same as the product of the number of the word lines and bit lines and the area that each of the memory cell occupies is 4 F² (2 F×2 F).

One end of memory cell 100 is electrically connected with a word line through word line contact point 110 and the other end is electrically connected with a bit line through bit line contact point 120. Word line contact points 110 are disposed with a four-time minimum processing dimension (4 F) along one word line and bit line contact points 120 are positioned with a four-time minimum processing dimension (4 F) along one bit line. Word line contact points 110 disposed along one word line are arranged alternately with word line contact points 110 disposed along an adjacent word line such that word lines 110 are arranged in a lozenge shape with a width and length of four-time minimum processing dimension (4 F), and bit line contact points 120 disposed along one bit line are arranged alternately with bit line contact points 120 disposed along an adjacent bit line such that the bit lines 120 are arranged in a lozenge shape with a width and length of four-time minimum processing dimension (4 F).

Two adjacent memory cells 100 are electrically connected to one word line contact point 110 and two adjacent memory cells 100 are electrically connected to one bit line contact point 120. Therefore, it looks like the memory cells 100 are connected in step shapes through the word line contact points 110 and bit line contact points 120. Further, the word line contact points of the present invention are in contact with a body.

Though not shown in FIG. 1, word line contact points 110 are disposed under the word lines and bit line contact points 120 are disposed under the bit lines.

The memory cell 110 is composed of transistor 130 and memory element 140. A source terminal of transistor 130 is electrically connected to a source line (SL), a gate terminal is electrically connected to word line WL1 through word line contact point 110, a drain terminal is connected to one end of memory element 140, and the other end of memory device 140 is electrically connected to bit line BL0 through bit line contact point 120. The gate terminal of transistor 130 is made of gate oxide in contact with word line contact point 110 and the drain terminal of transistor 130 is made of silicon implanted with N+ in contact with bit line contact point 120. The bit lines BL0 to BL6 are positioned at the upper portions of the memory cells 110, source lines are positioned at the lower ends of the memory cells, and two cells are connected to one gate trench 102. The detailed structure of the memory cell 100 is described below.

A method of manufacturing STT-RAM having a memory cell size of 4 F² according to the present invention from a semiconductor substrate is described hereafter.

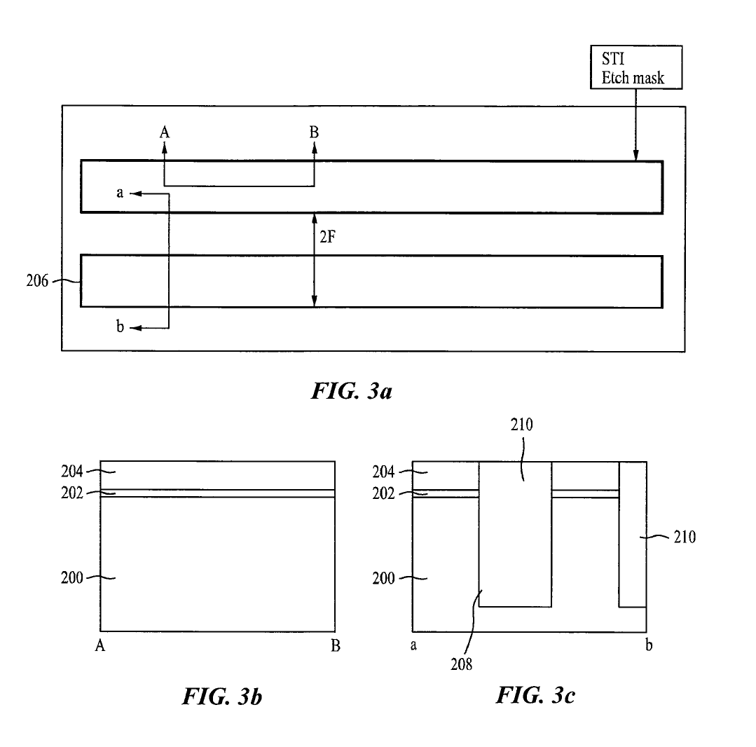

FIGS. 3a to 3c show a semiconductor substrate with a cell channel. FIG. 3a is a plan view, FIG. 3b is a cross-sectional view taken along line A-B in FIG. 3a, and FIG. 3c is a cross-sectional view taken along line a-b in FIG. 3a. The relationships of the figures are the same as those in the other figures described below.

Referring to FIGS. 3a to 3c, first insulating layer (SiO2) 202 is formed on semiconductor substrate 200 by oxidizing and second insulating layer (SiN) 204 is formed on first insulating layer 202 by Chemical Vapor Deposition (CVD). First insulating layer 202 allows second insulating layer 204 to be easily deposited on semiconductor substrate 200 and second insulating layer 204 functions as an etching mask or a polishing-stopping layer in the following processes.

A plurality of grooves 208 is formed by photographing and etching the semiconductor substrate 200 at a predetermined depth, using a Shallow Trench Isolation (STI) etching mask. The regions of grooves 208 include the regions where the drains are formed, in the regions where bit lines BL are formed later. STI oxide region 210 is formed in the groove 208.

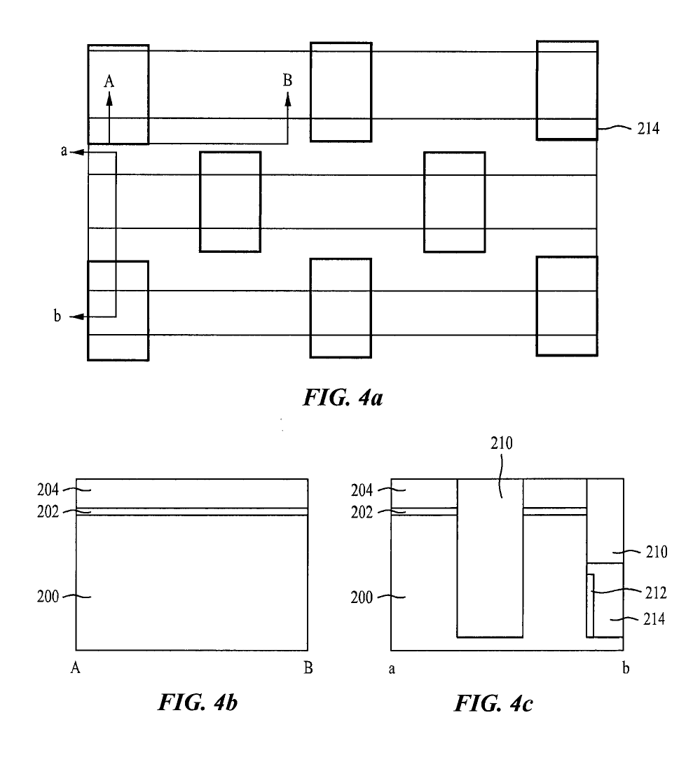

FIGS. 4a to 4c show the semiconductor substrate with embedded body contacts. In FIGS. 4a to 4c, oxide etching is performed on body contact region 214 and insulating layer spacer 212 for opening the body contact region 214 is formed. The insulating layer spacer 212 is filled with P+ or P-poly. Chemical Mechanical Polishing (CMP) is performed on the other portions of the body contact region 214, after oxide is performed.

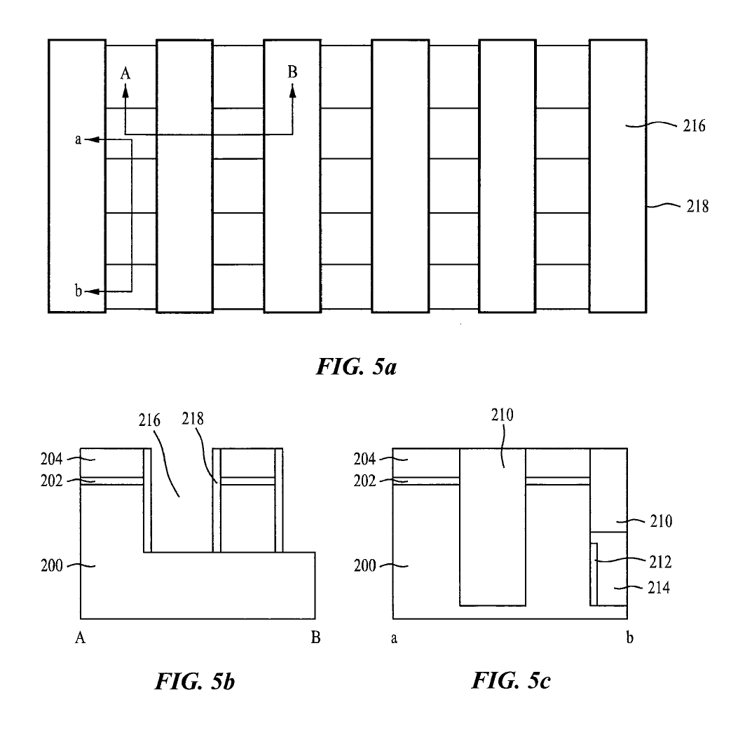

FIGS. 5a to 5c show the semiconductor substrate with a source line formed by a first etching. In FIGS. 5a and 5b, groove 216 is formed to a predetermined depth in semiconductor substrate 200 through first insulating layer 202 and second insulating layer 204, by the first source line etching. A source line spacer 218 is formed on the sides of groove 216 formed by the first source line etching.

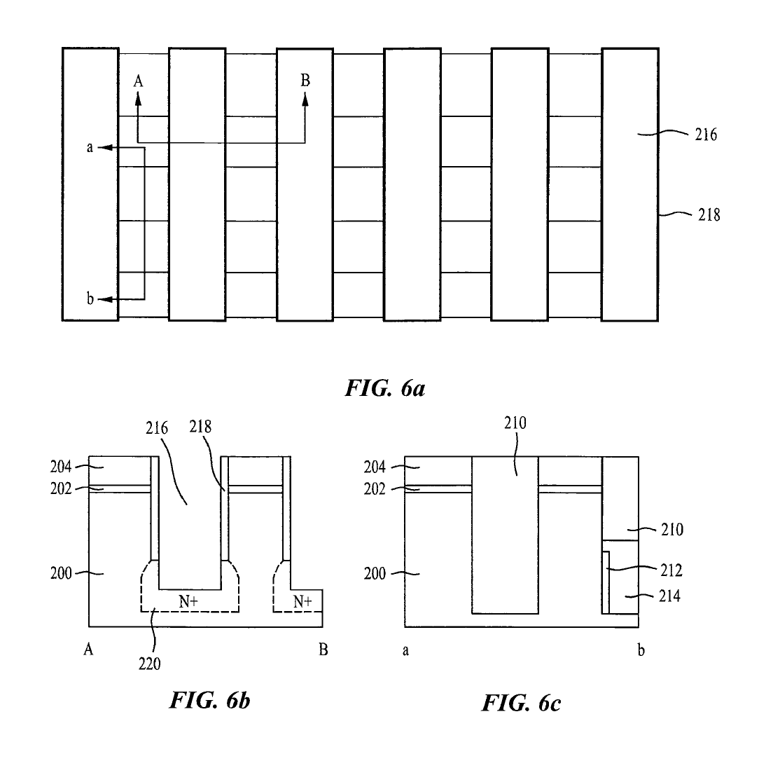

FIGS. 6a to 6c show the semiconductor substrate with a source line formed by a second etching. In FIGS. 6a to 6b, the second source line etching is performed at a predetermined depth in semiconductor substrate 200, under source line spacer 218 on the sides of groove 216 formed by source line-first etching. Source line junction N+ implanted region 220 is formed under and at the sides of the groove 216 formed by the second source line etching. N+ implanted region 220 is expanded by dispersing N+ ions horizontally to the sides by performing heat treatment after performing N+ implant on semiconductor substrate 200.

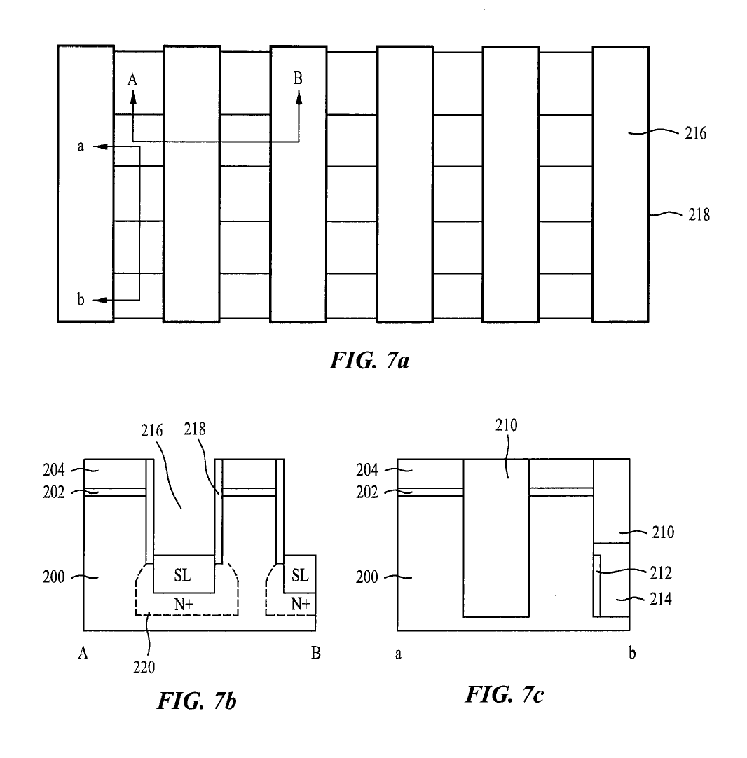

FIGS. 7a to 7c show the semiconductor substrate with the source line filled with metal. In FIGS. 7a and 7b, groove 216 formed by the first and second source line etchings is filled with metal that forms source line 222. Source line 222 is formed at a predetermined height from the bottom of groove 216 in contact with the source line spacer 218.

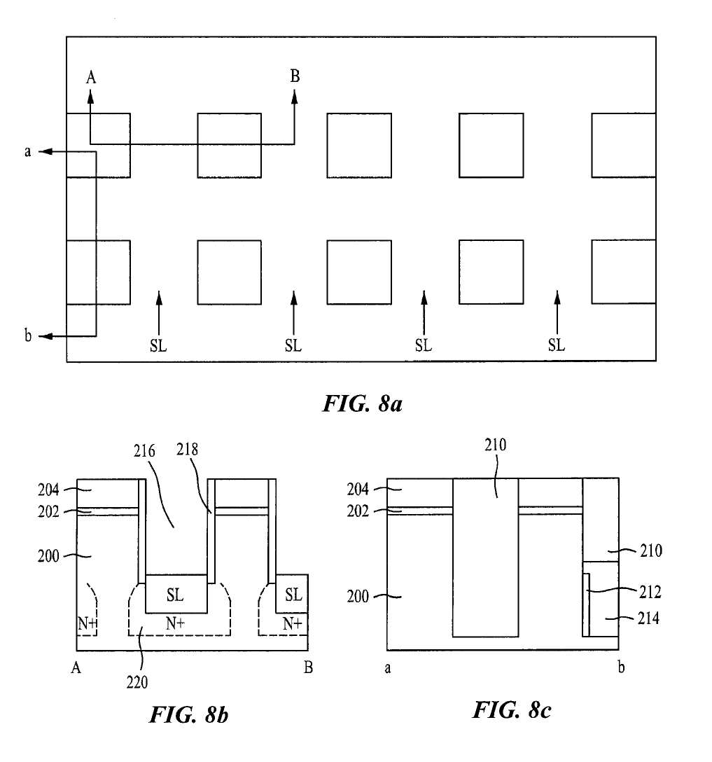

FIGS. 8a to 8c show a semiconductor substrate with an oxide region formed on the source line. In FIGS. 8a to 8b, an oxide region 224 is formed in the remaining portion of groove 216 on source line 222 formed at a predetermined height in groove 216. CMP is performed after oxide region 224 is formed.

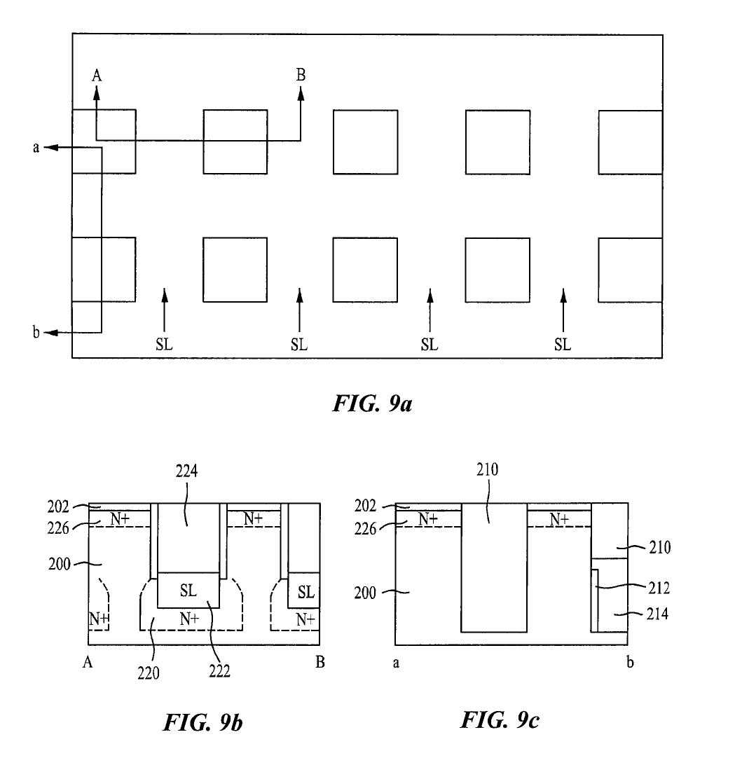

FIGS. 9a to 9c show a semiconductor substrate with the second insulating layer removed and an N+ implanted region formed. In FIGS. 9a and 9b, second insulating layer 204 formed on semiconductor substrate 200 is removed by CMP and N+ implanted region 226 implanted with N+ is formed under and at the sides of the first insulating layer 202. N+ implanted region 226 is expanded by dispersing N+ ions horizontally to the sides by performing heat treatment after performing N+ implant on semiconductor substrate 200.

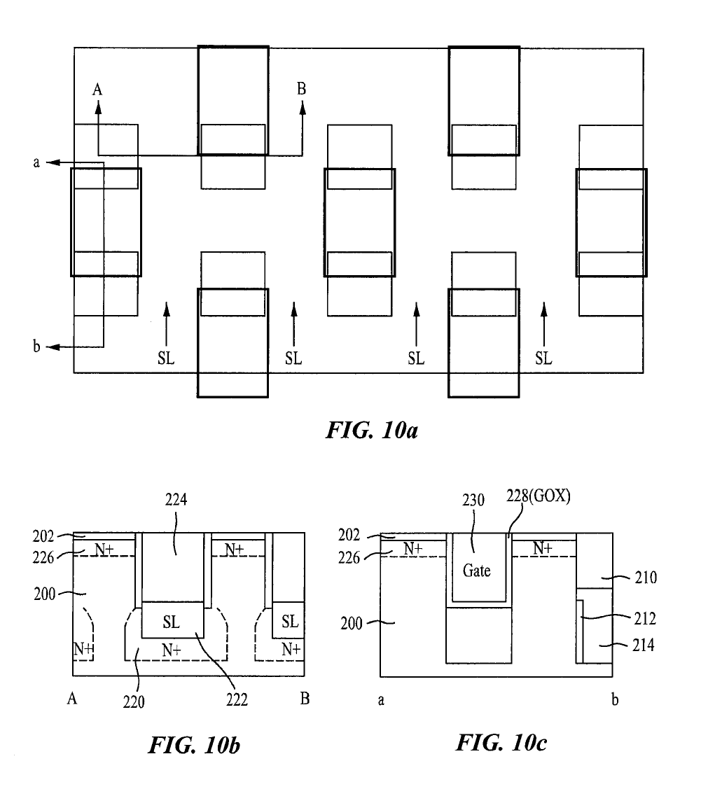

FIGS. 10a to 10c show the semiconductor substrate with a gate. In FIGS. 10a and 10b, the region where a gate is performed is etched, a gate oxide region 228 is formed on the bottom and the sides of the etched region, and gate 230 is formed by filling gate oxide region (GOX) 228 with gate metal.

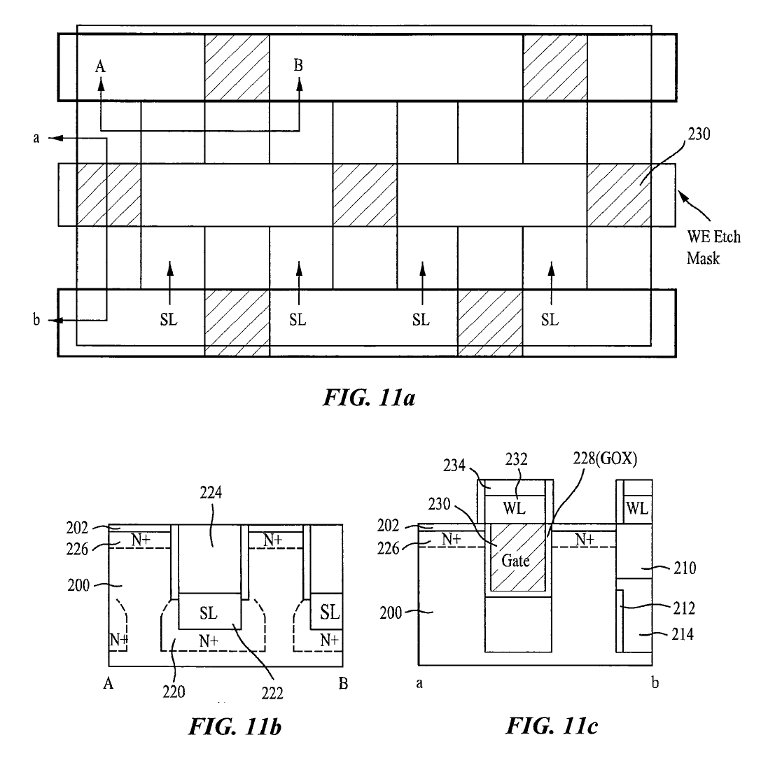

Next, FIGS. 11a to 11c show the semiconductor substrate with a word line WL. In FIGS. 11a to 11c, word line 232 is formed at a predetermined height on the region where gate 230 is formed and third insulating layer 234 is formed on the top and the sides of word line 232. The word line contact point is in body contact.

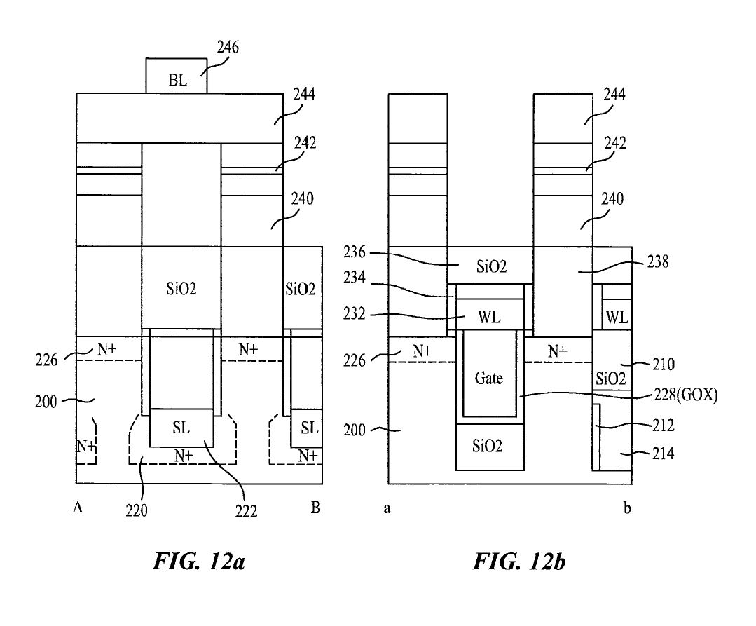

FIG. 12 shows the semiconductor substrate after a capacitor process. FIG. 12a shows the cross-section through which a bit line and source line pass and FIG. 12b shows the cross-section through which a word line passes. Fourth insulating layer 236 is formed on the third insulating layer 234. Storage node contact 238 is formed between third insulating layer 234 and fourth insulating layer 236. Lower electrode 240 and upper electrode 244 are formed above the storage node contact 238. Memory element 242 is formed between lower electrode 240 and upper electrode 244. Bit line (BL) 246 is formed on upper electrode 244.

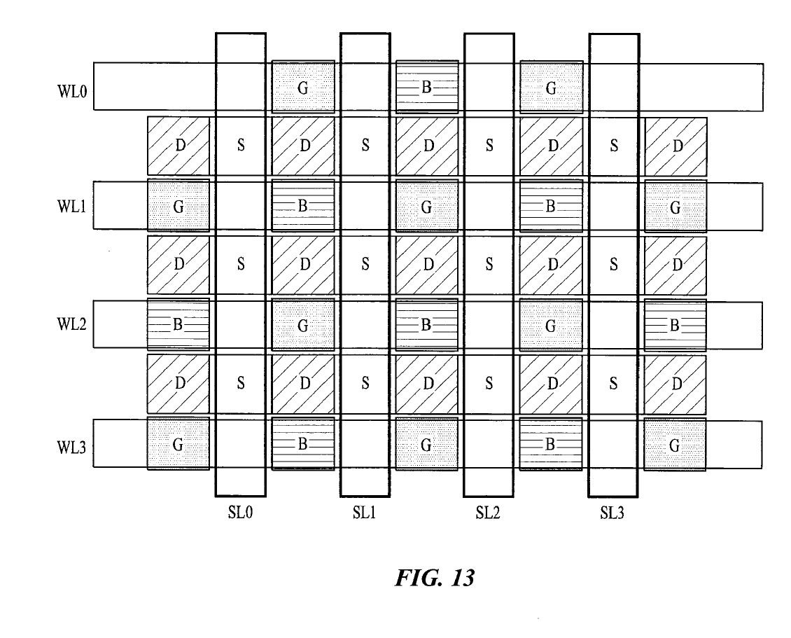

FIG. 13 shows a modification of the gate in the semiconductor substrate of the present invention. Two memory cells 100 that are adjacent to each other in the direction of source line SL, that is, the longitudinal direction, when seen from gate G, share gate G, and two memory cells 100 that are adjacent to each other in the direction of word line WL, that is, the transverse direction, share drain D. Therefore, memory cells 100 are arranged in step shapes in the sequence of gate G, drain D, source S, drain D, gate G, drain D, and source S, from lower left to upper right.

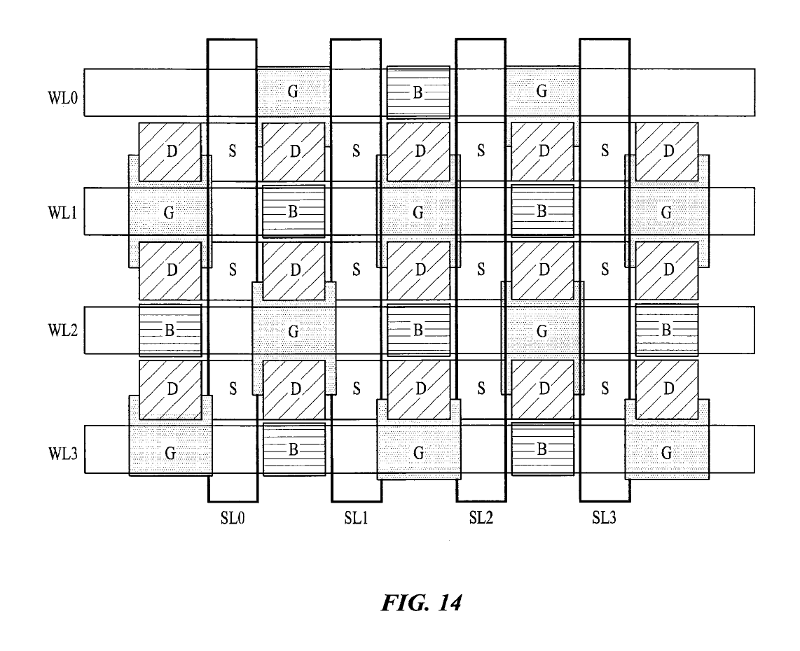

FIG. 14 shows another modification of the gate in the semiconductor substrate of the present invention. Two memory cells 100 that are adjacent to each other in the direction of source line SL, that is, the longitudinal direction, when seen from gate G, share gate G, and two memory cells 100 that are adjacent to each other in the direction of word line WL, that is, the transverse direction, share drain D. Therefore, memory cells 100 are arranged in step shapes in the sequence of gate G, drain D, source S, drain D, gate G, drain D, and source S, from lower left to upper right. However, the gate G expands to the adjacent drain D and source line SL to prevent variation of drain saturation current (IDSAT).

The primary feature of the present invention is allowing gate G to simultaneously drive two memory cells 100 formed adjacent to each other through a trench groove. That is, the gate terminal of the transistor fills an associated groove between two memory cells that are adjacent to each other in the direction of a bit line, and a plurality of memory cells covering simultaneously the sides of the two memory cells through the insulating layer formed between the gate and the two memory cells. Further, the gate connected to one word line for a plurality of word lines is connected with the gates of the transistors of two memory cells adjacent to each other in the direction of a bit line, such that two memory cells adjacent to each other in the direction of a bit line share the gate connected to one word line.

The two gates G are formed between memory cells 100 and the memory cells are driven through the gates G. The memory cell 100 is positioned between the word lines WL and connected by the sharing of gate G. The sharing connection of gates G of memory cells 100 is implemented alternately in the diagonal direction.

Although the present invention is described above with reference to the preferred embodiment, those skilled in the art can easily understand that the present invention may be varied and modified in various ways without departing from the spirit and scope of the present invention and it is apparent that the variation and modifications are included in the scope of claims.

What is claimed is:

1. A nonvolatile memory device comprising:
a plurality of word lines disposed in parallel with each other in one direction;
a plurality of bit lines disposed perpendicular to the word lines, in parallel with each other; and
a plurality of memory cells in which a transistor is provided, a source line is electrically connected to a source terminal of the transistor, a gate terminal of the transistor is electrically connected to the word lines, a drain terminal of the transistor is connected to one end of a memory element, the other end of the memory element is electrically connected to the bit line through a bit line contact point, the gate terminal of the transistor fills an associated one of grooves between two memory cells adjacent to each other in the direction of the bit line, and the memory cells simultaneously cover the sides between the two memory cells through the gate and an insulating layer formed between the two memory cells,
wherein the gate connected to one word line for each of a plurality of word lines is connected with the gates of the transistors of two memory cells adjacent to each other in the direction of the bit line such that two memory cells adjacent to each other in the direction of the bit line share the gate connected to one word line,
the gate terminal connected to the word line is disposed alternately with the gate terminal connected to an adjacent word line, the bit line contact point connected to the bit line is disposed alternately with the bit line contact point connected to an adjacent bit line,
the gate terminals of the transistors of adjacent two memory cells are electrically connected to one gate terminal,
the memory elements of two memory cells adjacent in the direction of a word line are electrically connected to one bit line contact point,
the drain terminals of the transistors of two memory cells electrically connected to the gate terminal through the memory elements are electrically connected to different bit lines through different bit line contact points, and
the bit line is disposed at the upper portion of the memory cell, a source line is disposed at the lower end of the memory cell, and two cells are connected to one gate trench.

2. The nonvolatile memory device according to claim 1, wherein each of a plurality of the word lines and the bit lines have a width and a gap of 2 F.

3. The nonvolatile memory device according to claim 1, wherein the memory cell is formed to have a size of 4 F².

4. The nonvolatile memory device according to claim 1, wherein the memory cell having a size of 4 F² is applied to STT-RAM, R-RAM, or PCRAM.

5. A nonvolatile memory device comprising:
a plurality of word lines disposed in parallel with each other in one direction;
a plurality of bit lines disposed perpendicular to the word lines, in parallel with each other; and
a plurality of memory cells in which a transistor is provided, a source line is electrically connected to a source terminal of the transistor, a gate terminal of the transistor is electrically connected to the word lines, a drain terminal of the transistor is connected to one end of a memory element, the other end of the memory element is electrically connected to the bit line through a bit line contact point, the gate terminal of the transistor fills an associated one of grooves between two memory cells adjacent to each other in the direction of the bit line, and the memory cells simultaneously cover the sides between the two memory cells through the gate and an insulating layer formed between the two memory cells,
wherein the gate connected to one word line for each of a plurality of word lines is connected with the gates of the transistors of two memory cells adjacent to each other in the direction of the bit line such that two memory cells adjacent to each other in the direction of the bit line share the gate connected to one word line,
the gate terminal connected to the word line is disposed alternately with the gate terminal connected to an adjacent word line, the bit line contact point connected to the bit line is disposed alternately with the bit line contact point connected to an adjacent bit line,
the gate terminals of the transistors of adjacent two memory cells are electrically connected to one gate terminal,
the memory elements of two memory cells adjacent in the direction of a word line are electrically connected to one bit line contact point,
the drain terminals of the transistors of two memory cells electrically connected to the gate terminal through the memory elements are electrically connected to different bit lines through different bit line contact points,
the bit line is disposed at the upper portion of the memory cell, a source line is disposed at the lower end of the memory cell, and two cells are connected to one gate trench,
the memory device further comprises a contact portion embedded in a semiconductor substrate and providing electric connection with the semiconductor substrate or a well formed in the semiconductor substrate.

6. The nonvolatile memory device according to claim 2, wherein each of a plurality of the word lines and the bit lines have a width and a gap of 2 F.

7. The nonvolatile memory device according to claim 2, wherein the memory cell is formed to have a size of 4 F².

8. The nonvolatile memory device according to claim 2, wherein the memory cell having a size of 4 F² is applied to STT-RAM, R-RAM, or PCRAM.

9. A method of manufacturing a nonvolatile memory device on a semiconductor substrate comprising:
a step of forming a device separation layer that forms a first insulating layer on a semiconductor substrate by oxidizing, forms a second insulating layer on the first insulating layer, forms a plurality of grooves by etching the semiconductor substrate by using an STI (Shallow Trench Isolation) etching mask, and then forms an STI oxide region in the grooves;
a step of forming an embedded body contact that oxide-etches a body contact region, forms an insulating spacer for opening the body contact region, and performs CMP (Chemical Mechanical Polishing) after filling the insulating spacer with P+ or P-poly and forming oxide in the remaining portion of the body contact region;
a step of forming source line-first etching that forms a groove at a predetermined depth in the semiconductor substrate through the first insulating layer and the second insulating layer by using source line-first etching, and forms a source line spacer on the sides of the groove formed by the source line-first etching;
a step of forming source line-second etching that performs source line-second etching at a predetermined depth in the semiconductor substrate, under the source line spacer formed on the sides of the groove by the source line-first etching, and forms a source line junction N+ implanted region under and at the sides of a groove formed by the source line-second etching;
a step of forming a source line that filling the grooves formed by the source line first-etching and the second-etching with metal that forms a source line;
a step of filling a source line that forms an oxide region in the remaining portion of the groove, on the source line formed at a predetermined height in the groove;
a step of removing an insulating layer and forming an N+ implanted region that removes the second insulating layer formed on the semiconductor substrate by performing CMP and an N+-implanted N+ implant region under and at the sides of the first insulating layer;
a step of forming a gate that etches a region where a gate is formed in the STI oxide region, forms a gate oxide region on the sides and the bottom of the etched region, and forms a gate by filling the gate oxide region with gate metal; and
a step of forming a word line that forms a word line at a predetermined height on the region where the gate is formed, and forms a third insulating layer on the top and the sides of the word line.

10. The method of manufacturing a nonvolatile memory device according to claim 9, further comprising a step that forms a fourth insulating layer on the third insulating layer formed on the top and the sides of the word line, forms a storage node contact between the third insulating layer and the fourth insulating layer, forms a lower electrode and an upper electrode on the storage node contact, forms a memory element between the lower electrode and the upper electrode, and a bit line is formed on the upper electrode.
